(19) United States
(12) Patent Application Publication
(10) Pub. No.: US 2022/0098791 A1
(43) Pub. Date: Mar. 31, 2022

(54) EXPERIMENTAL SYSTEM FOR STUDYING REFINING MECHANISM AND CHARACTERISTIC OF REFINER PLATE AND METHOD FOR OPERATING SAME

(71) Applicant: SHAANXI UNIVERSITY OF SCIENCE & TECHNOLOGY, Xi'an (CN)

(72) Inventors: Jixian DONG, Xi'an (CN); Huan LIU, Xi'an (CN); Bo WANG, Xi'an (CN); Chuanwu DUAN, Xi'an (CN); Kai QI, Xi'an (CN); Xiya GUO, Xi'an (CN); Lijie QIAO, Xi'an (CN); Sha WANG, Xi'an (CN)

(21) Appl. No.: 17/548,738

(22) Filed: Dec. 13, 2021

(30) Foreign Application Priority Data
May 6, 2021 (CN) 202110491968.9

(51) Int. Cl. D21D 1/30; D21D 1/00

(52) U.S. Cl. CPC D21D 1/306; D21D 1/002

(57) ABSTRACT

An experimental system for studying a refining mechanism and characteristic of a refiner plate, including a disc refiner unit, a first storage tank, a second storage tank, a circulating pump, a pipeline system, a detection device for measuring process variables including flow, pressure and temperature, and a data acquisition and control system. An operation parameter control system is provided to control an operation state of valves at different positions of the pipeline system to achieve the switching of the operation mode of the experimental system. The data acquisition and control system is configured to collect the parameters at different detection points. A method for operating the experimental system is also provided.

### CROSS-REFERENCE TO RELATED APPLICATIONS

This application claims the benefit of priority from Chinese Patent Application No. 202110491968.9, filed on May 6, 2021. The content of the aforementioned application, including any intervening amendments thereto, is incorporated herein by reference in its entirety.

### TECHNICAL FIELD

The application relates to pulp and papermaking technology, and more particularly to an experimental system for studying a refining mechanism and characteristic of a refiner plate and a method for operating the same.

### BACKGROUND

Refining is an important step in the papermaking, pulping and the production of reconstituted tobacco by a papermaking process, and it is able to improve the properties of the pulp and fibers to adapt to the production of paper with various performances. Currently, the refining process is performed mainly by a disc refiner, a conical refiner or a cylindrical refiner, among which the disc refiner is the most commonly used, and is relatively easy to control. However, the basic research on the refining mechanism and characteristic of the plates of the disc refiner is still insufficient, and the selection of the refiner plates and refiner is mainly based on experience, which may lead to an improper plate selection, lower refining efficiency, higher energy consumption, and poor pulp or fiber quality.

The research on the refining mechanism and characteristic of the refiner plates is of great significance for the control of the refining process and pulp quality, and is beneficial to reduce the energy consumption and improve the refining quality and efficiency. The control method of the disc refiner mainly includes constant-power control and constant-beating degree control, in which the plate clearance is an important parameter that would directly affect the refining power. Though the plate clearance may not fall within the consideration in actual production, it is actually a key parameter for the investigation of the refining mechanism. The study on pulp refining in laboratory mainly adopts a cyclical refining method, whereas in the actual production, a multi-stage refining conducted by the disc refiners is commonly employed. Therefore, the experimental system used in the research of pulp refining should be as close to the actual one as possible. The control parameters in the actual pulp refining mainly includes temperature, pressure, rotation speed, flow and power, whereas the gap clearance is additionally considered in the experimental research. However, the existing experimental devices fail to meet the requirements mentioned above. Thus, a well-equipped refining system is in need to explore the refining mechanism and characteristics of different plates under different control methods, aiming to establish an improved refining mechanism which can be used to optimize the actual pulp refining process.

### SUMMARY

In order to overcome the above-mentioned defects in the prior art, an objective of the present disclosure is to provide an experimental system for studying a refining mechanism and characteristic of a refiner plate and a method for operating the same. The experimental system described has a strong operability and compact structure, and can be applied to the study of the refining mechanism and characteristic of a refining disc under different operation modes.

The technical solutions of the present disclosure are described as follows.

In a first aspect, the present disclosure provides an experimental system for studying a refining mechanism and characteristic of a refiner plate, comprising:

a disc refiner unit;

a first storage tank;

a second storage tank;

a circulating pump;

a control and data acquisition system;

a first three-way joint;

a second three-way joint;

a first inlet pipeline;

a second inlet pipeline; and

a third inlet pipeline; and

a third outlet pipeline;

wherein an outlet of the first storage tank is connected to a first outlet pipeline; an outlet of the second storage tank is connected to a second outlet pipeline; an end of the first outlet pipeline away from the first storage tank and an end of the second outlet pipeline away from the second storage tank are respectively connected to the circulating pump through the first three-way joint; the circulating pump is connected to an inlet of the disc refiner unit through the third inlet pipeline; the third outlet pipeline is connected to an outlet of the disc refiner unit; the third outlet pipeline is connected to the first inlet pipeline and the second inlet pipeline through the second three-way joint; an end of the first inlet pipeline away from the third outlet pipeline is connected to an inlet of the first storage tank; and an end of the second inlet pipeline away from the third outlet pipeline is connected to an inlet of the second storage tank;

the disc refiner unit is connected to an operation parameter control and detection device; the first outlet pipeline is provided with a first outlet control valve; the second outlet pipeline is provided with a second outlet control valve; the third inlet pipeline is provided with a first temperature and pressure measuring point; the third outlet pipeline is provided with a second temperature and pressure measuring point; the third inlet pipeline is provided with a flowmeter; the first inlet pipeline is provided with a first inlet control valve; and the second inlet pipeline is provided with a second inlet control valve; and

the disc refiner unit, the circulating pump, the operation parameter control and detection device, the first outlet control valve, the second outlet control valve, the flowmeter, the first inlet control valve, the second inlet control valve, the first temperature and pressure measuring point and the second temperature and pressure measuring point are all connected to the control and data acquisition system.

In some embodiments, the disc refiner unit comprises a motor, a coupling, a main shaft, a rotor assembly and a stator assembly; the motor is connected to the main shaft through the coupling; the main shaft is connected to the rotor assembly; the rotor assembly is connected to the stator assembly; the operation parameter control and detection device comprises a motor inverter, a power sensor, a gap adjustment device and a linear displacement sensor; the motor inverter and the power sensor are respectively connected to the motor; and the gap adjustment device and the linear displacement sensor are respectively connected to the main shaft.

In some embodiments, the first temperature and pressure measuring point on the third inlet pipeline comprises a first temperature transmitter and a first pressure transmitter; and the second temperature and pressure measuring point on the third outlet pipeline comprises a second temperature transmitter and a second pressure transmitter.

In some embodiments, the third inlet pipeline is provided with an inlet master valve; the third inlet pipeline is connected to a drain pipe; and the drain pipe is provided with a drain valve.

In some embodiments, the third outlet pipeline is provided with an outlet pressure regulating valve.

In some embodiments, the third outlet pipeline is connected to a sampling pipe; and the sampling pipe is provided with a sampling valve.

In some embodiments, the circulating pump is connected to a pump inverter; and the pump inverter is connected to the control and data acquisition system.

In some embodiments, the control and data acquisition system is connected to a communication module; and the communication module is configured for communicating and interconnecting with an upper computer.

In a second aspect, the present disclosure further provides a method for operating the experimental system mentioned above, wherein the method comprises a constant-gap circulation mode, a constant-gap series mode, a constant-power circulation mode and a constant-power series mode;

the constant-gap circulation mode is performed through steps of:

setting, by the operation parameter control and detection device, a gap value of the disc refiner unit; selecting the first storage tank or the second storage tank as a circulating storage tank; opening the first inlet control valve and the first outlet control valve of the first storage tank and closing the second inlet control valve and the second outlet control valve of the second storage tank, or opening the second inlet control valve and the second outlet control valve of the second storage tank and closing the first inlet control valve and the first outlet control valve of the first storage tank; turning on the flowmeter, the disc refiner unit, the circulating pump, the first temperature and pressure measuring point and the second first temperature and pressure measuring point; maintaining, by the operation parameter control and detection device, a gap of the disc refiner unit at a set gap value; and transmitting measured experimental data to the control and data acquisition system;

the constant-gap series mode is performed through steps of:

setting, by the operation parameter control and detection device, a gap value of the disc refiner unit; selecting the first storage tank as an initial pre-refining tank and the second storage tank as a post-refining tank; closing the first inlet control valve of the first storage tank and opening the first outlet control valve or closing the second inlet control valve of the second storage tank and opening the second outlet control valve; opening the second inlet control valve of the second storage tank and closing the second outlet control valve or opening the first inlet control valve of the first storage tank and closing the first outlet control valve; turning on the flowmeter, the disc refiner unit, the circulating pump, the first temperature and pressure measuring point and the second temperature and pressure measuring point; maintaining, by the operation parameter control and detection device, a gap of the disc refiner unit at a set gap value; transmitting measured experimental data to the control and data acquisition system; and after a single refining is completed, interchanging the initial pre-refining tank and the post-refining tank, and repeating the above steps;

the constant-power circulation mode is performed through steps of:

setting, by the operation parameter control and detection device, a power value of the disc refiner unit; selecting the first storage tank or the second storage tank as a circulating storage tank; opening the first inlet control valve and the first outlet control valve of the first storage tank and closing the second inlet control valve and the second outlet control valve of the second storage tank, or opening the second inlet control valve and the second outlet control valve of the second storage tank and closing the first inlet control valve and the first outlet control valve of the first storage tank; turning on the flowmeter, the disc refiner unit, the circulating pump, the first temperature and pressure measuring point and the second temperature and pressure measuring point; maintaining, by the operation parameter control and detection device, a power of the disc refiner unit at a set power value; and transmitting measured experimental data to the control and data acquisition system; and the constant-power series mode is performed through steps of: setting, by the operation parameter control and detection device, a power value of the disc refiner unit; selecting the first storage tank as an initial pre-refining tank and the second storage tank as a post-refining tank; closing the first inlet control valve of the first storage tank and opening the first outlet control valve or closing the second inlet control valve of the second storage tank and opening the second outlet control valve; opening the second inlet control valve of the second storage tank and closing the second outlet control valve or opening the first inlet control valve of the first storage tank and closing the first outlet control valve; turning on the flowmeter, the disc refiner unit, the circulating pump, the first temperature and pressure measuring point and the second temperature and pressure measuring point; maintaining, by the operation parameter control and detection device, a power of the disc refiner unit at a set power value; transmitting measured experimental data to the control and data acquisition system; and after a single refining is completed, interchanging the initial pre-refining tank and the post-refining tank, and repeating the above steps.

In some embodiments, in each mode, when a refining test is carried out, a refined pulp is sampled and tested; and after the refining test is completed, the entire experimental system is drained and cleaned.

Compared to the prior art, the present disclosure has the following beneficial effects.

The experimental system disclosed herein for studying the refining mechanism and characteristic of a disc refiner plate achieves the switching among different operation modes through setting a first storage tank, a second storage tank and their connecting pipelines under the control of an operation parameter control and detection device and multiple valves, and the refining mechanism and characteristic of the disc refiner plate under different operation modes can be studied according to various parameters at different measuring points collected by a control and data acquisition system. The experimental system has compact structure, simple use, multiple functions and high automation degree, and the structure and operation of such experimental system meet the requirements of actual production and experimental study of the refining mechanism and characteristic of the disc refiner. The experimental system can be applied to the collection of relevant experimental data and theoretical construction and verification, and has a promising application prospect.

In addition, a motor inverter is provided to control a rotating speed of the disc refiner; a power sensor is provided to measuring a current vale; a gap adjustment device is provided to adjust and stabilize a gap of the disc refiner; and a linear displacement sensor is provided to monitor the gap during the installation and operation of the disc refiner. These components can monitor the operation parameters of the experimental system in real time to meet the experimental requirement.

Furthermore, an inlet master valve is provided to cooperate with a circulating pump to control and adjust the flow rate and inlet pressure, and can be closed in an emergency to improve the safety of the experimental system. A drain valve is provided to clean and drain the experimental system after a single experiment.

An outlet pressure regulating valve is provided to adjust a pressure difference between the inlet and outlet of the disc refiner.

A sampling valve is provided to sample and analyze a paper pulp while the experimental system is running.

A pump inverter is provided to adjust a rotating speed of the circulating pump, so as to adjust the flow rate and inlet pressure to meet the experimental requirement.

The control and data acquisition system is provided to communicate and interconnect with an upper computer through a communication module, and transmit data to the upper computer in real time for processing and analysis.

A method provided herein for operating the experimental system has strong operability and high degree of automation, and can be applied to the investigation of the refining mechanism and characteristic of a disc refiner under different operation modes.

### BRIEF DESCRIPTION OF THE DRAWINGS

FIG. 1 schematically depicts a structure of an experimental system for studying a refining mechanism and characteristic of a refining disc in accordance with an embodiment of the present disclosure;

FIG. 2 is a flow chart of operation of the experimental system in accordance with an embodiment of the present disclosure; and

FIG. 3 schematically depicts an arrangement of a sensor of a disc refiner assembly.

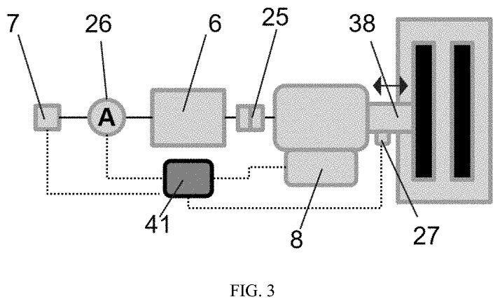

In the drawings, 1, flowmeter; 2, first temperature transmitter; 3, first pressure transmitter; 4, movable plate assembly; 5, fixed plate assembly; 6, motor; 7, motor inverter; 8, gap adjustment device; 9, second pressure transmitter; 10, second temperature transmitter; 11, outlet pressure regulating valve; 12, sampling valve; 13, first inlet control valve; 14, second inlet control valve; 15, first storage tank; 16, second storage tank; 17, first outlet control valve; 18, second outlet control valve; 19, circulating pump; 20, pump inverter; 21, drain valve; 22, inlet master valve; 23, control and data acquisition system; 24, communication module; 25, coupling; 26, power sensor; 27, linear displacement sensor; 28, second three-way joint; 29, first three-way joint; 30, first inlet pipeline; 31, second inlet pipeline; 32, third inlet pipeline; 33, first outlet pipeline; 34, second outlet pipeline; 35, third outlet pipeline; 36, first temperature and pressure measuring point; 37, second temperature and pressure measuring point; 38, main shaft; 39, sampling pipe; 40, drain pipe; 41, operation parameter control and detection device; 42, upper computer; and 43, disc refiner unit.

### DETAILED DESCRIPTION OF EMBODIMENTS

The structure and working principle of the present disclosure will be further described in detail below with reference to the accompanying drawings and embodiments.

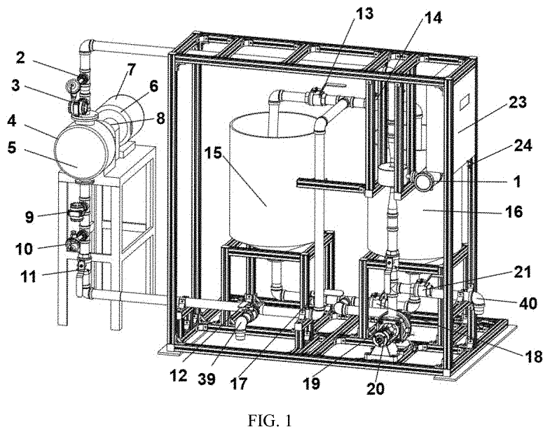

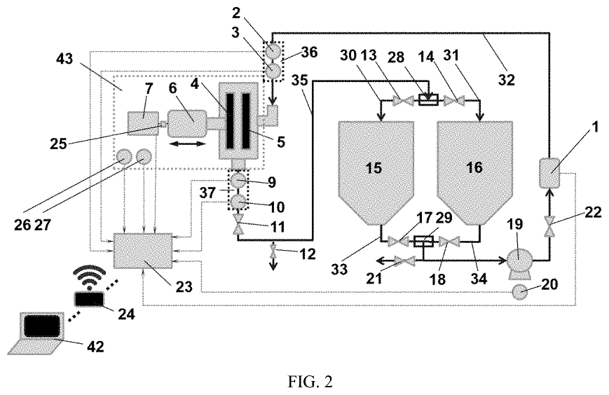

As shown in FIGS. 1-2, an experimental system for studying a refining mechanism and characteristic of a refining disc is provided, which includes a disc refiner unit 43, a first storage tank 15, a second storage tank 16, a circulating pump 19, a control and data acquisition system 23, a first three-way joint 29, a second three-way joint 28, a first inlet pipeline 30, a second inlet pipeline 31 and a third inlet pipeline 32. An outlet of the first storage tank 15 is connected to a first outlet pipeline 33. An outlet of the second storage tank 16 is connected to a second outlet pipeline 34. An end of the first outlet pipeline 33 away from the first storage tank 15 and an end of the second outlet pipeline 34 away from the second storage tank 16 are respectively connected to the circulating pump 19 through the first three-way joint 29. The circulating pump 19 is connected to an inlet of the disc refiner unit 43 through the third inlet pipeline 32. A third outlet pipeline 35 is connected to an outlet of the disc refiner unit 43. The third outlet pipeline 35 is connected to the first inlet pipeline 30 and the second inlet pipeline 31 through the second three-way joint 28. An end of the first inlet pipeline 30 away from the third outlet pipeline 35 is connected to an inlet of the first storage tank 15. An end of the second inlet pipeline 31 away from the third outlet pipeline 35 is connected to an inlet of the second storage tank 16.

The disc refiner unit 43 is connected to an operation parameter control and detection device 41. The first outlet pipeline 33 is provided with a first outlet control valve 17. The second outlet pipeline 34 is provided with a second outlet control valve 18. The third inlet pipeline 32 is provided with a first temperature and pressure measuring point 36. The third outlet pipeline 35 is provided with a second temperature and pressure measuring point 37. The third inlet pipeline 32 is provided with a flowmeter 1. The first inlet pipeline 30 is provided with a first inlet control valve 13. The second inlet pipeline 31 is provided with a second inlet control valve 14.

The disc refiner unit 43, the circulating pump 19, the operation parameter control and detection device 41, the first outlet control valve 17, the second outlet control valve 18, the flowmeter 1, the first inlet control valve 13, the second inlet control valve 14, the first temperature and pressure measuring point 36 and the second temperature and pressure measuring point 37 are all connected to the control and data acquisition system 23.

As shown in FIG. 2, in an embodiment, the disc refiner unit 43 includes a motor 6, a coupling 25, a main shaft 38, a movable plate assembly 4 and a fixed plate assembly 5. The motor 6 is connected to the main shaft 38 through the coupling 25. The main shaft 38 is connected to the movable plate assembly 4. The movable plate assembly 4 is connected to the fixed plate assembly 5. The operation parameter control and detection device 41 includes a motor inverter 7, a power sensor 26, a gap adjustment device 8 and a linear displacement sensor 27. The motor inverter 7 and the power sensor 26 are respectively connected to the motor 6. The gap adjustment device 8 and the linear displacement sensor 27 are respectively connected to the main shaft 38.

In an embodiment, the first temperature and pressure measuring point 36 on the third inlet pipeline 32 includes a first temperature transmitter 2 and a first pressure transmitter 3. The second temperature and pressure measuring point 37 on the third outlet pipeline 35 includes a second temperature transmitter 10 and a second pressure transmitter 9.

In an embodiment, the third inlet pipeline 32 is provided with an inlet master valve 22. The third inlet pipeline 32 is connected to a drain pipe 40. The drain pipe 40 is provided with a drain valve 21.

In an embodiment, the third outlet pipeline 35 is provided with an outlet pressure regulating valve.

In an embodiment, the third outlet pipeline 35 is connected to a sampling pipe 39. The sampling pipe 39 is provided with a sampling valve 12.

In an embodiment, the circulating pump 19 is connected to a pump inverter 20. The pump inverter is connected to the control and data acquisition system 23.

In an embodiment, the control and data acquisition system 23 is connected to a communication module 24. The communication module 24 is configured for communicating and interconnecting with an upper computer 42.

The structure and a working method of the experimental system for studying the refining mechanism and characteristic of the disc refiner is further described with reference to a specific embodiment.

As shown in FIG. 1, the experimental system for studying the refining mechanism and characteristic of the disc refiner includes the disc refiner unit 43, a slurry storage and flow system and the control and data acquisition system 23. The disc refiner unit 43 includes the motor 6, a support, the main shaft 38, the movable plate assembly 4 and the fixed plate assembly 5. The movable plate assembly 4 includes a rotating base and a movable refining plate. The rotating base is connected to the main shaft 38. The fixed plate assembly 5 includes a base and a fixed refining plate. The base is integrated with the support. A pipeline system includes the first storage tank 15, the second storage tank 16, the inlet and outlet control valve of the first storage tank 15, the inlet and outlet control valve of the second storage tank 16, the drain valve 21, the circulating pump 19, the outlet pressure regulating valve 11 and the sampling valve 12. A control system is controlled by a programmable logic controller (PLC). The control system includes refining disc gap measurement, an automatic gap adjustment mechanism, the motor inverter 7 and the pump inverter 20 to control a gap, a power and a speed of the disc refiner and control a flow of a system and a pressure at an inlet of the disc refiner. A data acquisition system includes a measuring element and a signal acquisition and transmission device. The measuring element includes the flowmeter 1, the first pressure transmitter 3, the first temperature transmitter 2, the second pressure transmitter 9, the second temperature transmitter 10, a disc-gap detection sensor and a sensor for detecting voltage, current and speed of the disc refiner. The measuring element is configured to collect a rotating speed of a pump, a flow, an inlet and outlet pressure, an inlet and outlet temperature, a power of the disc refiner, a rotating speed of the disc refiner and a gap of the disc refiner in real time and transmit the measured data to the data acquisition system for processing.

A refining plate of the disc refiner unit 43 is replaceable. The disc refiner is provided with an inverter to control the rotating speed of the disc refiner. The disc refiner is provided with the disc-gap detection sensor to detect the gap of the disc refiner in real time.

A slurry storage and feeding system includes the first storage tank 15, the second storage tank 16, the inlet and outlet control valves of the first storage tank 15, the inlet and outlet control valves of the second storage tank 16, and the drain valve 21, the circulating pump 19, the outlet pressure regulating valve 11 and the sampling valve 12. Both the inlet of the first storage tank 15 and the inlet of the second storage tank 16 are connected to a pipeline, and the pipeline entering storage tanks is divided into two paths through a three-way joint before entering the first storage tank 15 and the second storage tank 16. The two paths are respectively provided with an inlet control valve. Both the outlet of the first storage tank 15 and the second storage tank 16 are connected to a pipeline. Two paths leaving storage tanks are joint into one pipeline through a three-way joint and is connected to the circulating pump 19, and the two paths are respectively provided with an outlet control valve. A pipeline behind the circulating pump 19 is a first vertical pipeline, and is provided with the flowmeter 1. The flowmeter 1 is connected to the first vertical pipeline through a clamp. After passing through the flowmeter 1, the pipeline is horizontally connected to the inlet of the disc refiner. An end of the horizontally-arranged pipeline is connected to a metal flexible tube. An end of the metal flexible tube is connected to a second vertical pipeline of a flange at the inlet of the disc refiner through a clamp. The second vertical pipeline of the flange is provided with the first temperature transmitter 2 and the first pressure transmitter 3 from top to bottom. An outlet of the disc refiner is provided with a third vertical pipeline, and the third vertical pipeline is connected to the disc refiner through a flange. The third vertical pipeline is provided with the second pressure transmitter 9, the second temperature transmitter 10 and the outlet pressure regulating valve 11. The third vertical pipeline is connected to a horizontal pipeline.

The horizontal pipeline is provided with the sampling valve 12. The sampling valve is connected to the horizontal pipeline through a three-way joint. The horizontal pipeline is connected to the pipeline connected to the inlet of the first storage tank 15 and the inlet of the second storage tank 16.

D is gap is measured through the linear displacement sensor in a scale-display manner. The main shaft of the disc refiner is provided with the linear displacement sensor 27. The disc gap is adjusted by the gap adjustment device 8 through controlling an axial movement of the main shaft 38. The pump inverter 20 is connected to the circulating pump 19. The motor inverter 7 is connected to the motor 6.

A constant gap control of the disc refiner may be realized by setting a value of the dis gap, and a constant power control of the disc refiner is realized through an automatic adjustment of the disc gap and setting a constant power value. A flow of the circulating pump 19 is adjusted through adjusting a rotating speed of the pump inverter 29, and a real-time adjustment of the rotating speed can realize a constant flow rate of a system and a constant inlet pressure of a refining zone.

A method for using the experimental system includes the following steps.

(1) After installing a refining disc, the disc refiner is locked and the measuring element is started.

(2) The experimental system is feed with water or slurry. The circulating pump 19 is turned on. When the experimental system is operating normally, the disc gap is calibrated.

(3) After the disc gap is calibrated, the drain valve 21 is opened to clean the experimental system.

(4) A working mode of the experimental system is determined.

When in a constant-gap circulation mode, a value of the disc gap is set according to a requirement of an experiment, such that a gap between a movable refining plate to a fixed refining plate reaches the set value. The second storage tank 16 is selected. The first inlet control valve 13 and the first outlet control valve 17 are closed. The second inlet control valve 14 and the second outlet control valve 18 are opened to realize a single tank circulation of the experimental system. Similarly, the first storage tank 15 may also be selected. A pretreated slurry is loaded into a corresponding storage. After the pretreated slurry is stable, a refining system is turned on. A startup sequence set by the system is detection devices (flowmeter 1, the first temperature transmitter 2, the first pressure transmitter 3, the second pressure transmitter 9, the second temperature transmitter 10), the disc refiner unit 43, the circulating pump 19. The gap adjustment device 8 is configured to stabilize the disc gap at the set value. The disc gap may be adjusted according to an actual experimental condition. During an experiment, all experimental data will be collected by the control and data acquisition system 23 and transmitted to a computer in real time.

When in a constant-power series mode, a value of a power is set according to the requirement of the experiment, such that an operating power of the disc refiner reaches the set value. The first storage tank 15 is selected as an initial pre-refining tank, and the second storage tank 16 is selected as a post-refining tank. Therefore, in an initial state, the first inlet control valve 13 and the second outlet control valve 18 are closed, and the second inlet control valve 14 and the first outlet control valve 17 should be opened. After refining is completed, if the refining is performed in series, the first inlet control valve 13 and the second outlet control valve 18 are opened, and the second inlet control valve 14 and the first outlet control valve 17 are closed and so on to realize multi-stage refining.

(5) During the experiment, all experimental data will be collected through the data acquisition system and transmitted to the computer in real time.

(6) A sampling mode is determined, and a sampling is carried out at the sampling valve 12.

(7) After the experiment is completed, the drain valve 21 is opened, and the disc refiner unit 43 and the circulating pump 19 are operating at the same time. When the experimental system is drained, the disc refiner unit 43, the circulating pump 19 and the drain valve 21 are turned off. After adding an appropriate amount of water to the storage tanks the disc refiner unit 43 is turned on and then the circulating pump 19 is turned on to flush the experimental system.

Mentioned above are merely preferred embodiments of the disclosure, which are illustrative of the technical solutions of the present disclosure. These embodiments are not intended to limit this disclosure, and it should be noted that any modifications, combinations and replacements made by those skilled in the art without departing from the spirit of the present disclosure should fall within the scope of the present disclosure defined by the appended claims.

What is claimed is:

1. An experimental system for studying a refining mechanism and characteristic of a refining disc, comprising:
a disc refiner unit;
a first storage tank;
a second storage tank;
a circulating pump;
a control and data acquisition system;
a first three-way joint;
a second three-way joint;
a first inlet pipeline;
a second inlet pipeline;
a third inlet pipeline; and
a third outlet pipeline;
wherein an outlet of the first storage tank is connected to a first outlet pipeline;
an outlet of the second storage tank is connected to a second outlet pipeline; an end of the first outlet pipeline away from the first storage tank and an end of the second outlet pipeline away from the second storage tank are respectively connected to the circulating pump through the first three-way joint; the circulating pump is connected to an inlet of the disc refiner unit through the third inlet pipeline; the third outlet pipeline is connected to an outlet of the disc refiner unit; the third outlet pipeline is connected to the first inlet pipeline and the second inlet pipeline through the second three-way joint; an end of the first inlet pipeline away from the third outlet pipeline is connected to an inlet of the first storage tank; and an end of the second inlet pipeline away from the third outlet pipeline is connected to an inlet of the second storage tank;
the disc refiner unit is connected to an operation parameter control and detection device; the first outlet pipeline is provided with a first outlet control valve; the second outlet pipeline is provided with a second outlet control valve; the third inlet pipeline is provided with a first temperature and pressure measuring point; the third outlet pipeline is provided with a second temperature and pressure measuring point; the third inlet pipeline is provided with a flowmeter; the first inlet pipeline is provided with a first inlet control valve; and the second inlet pipeline is provided with a second inlet control valve; and
the disc refiner unit, the circulating pump, the operation parameter control and detection device, the first outlet control valve, the second outlet control valve, the flowmeter, the first inlet control valve, the second inlet control valve, the first temperature and pressure measuring point and the second temperature and pressure measuring point are all connected to the control and data acquisition system.

2. The experimental system of claim 1, wherein the disc refiner unit comprises a motor, a coupling, a main shaft, a movable plate assembly and a fixed plate assembly;
the motor is connected to the main shaft through the coupling; the main shaft is connected to the movable plate assembly; the movable plate assembly is connected to the fixed plate assembly; the operation parameter control and detection device comprises a motor inverter, a power sensor, a gap adjustment device and a linear displacement sensor; the motor inverter and the power sensor are respectively connected to the motor; and the gap adjustment device and the linear displacement sensor are respectively connected to the main shaft.

3. The experimental system of claim 1, wherein the first temperature and pressure measuring point on the third inlet pipeline comprises a first temperature transmitter and a first pressure transmitter; and the second temperature and pressure measuring point on the third outlet pipeline comprises a second temperature transmitter and a second pressure transmitter.

4. The experimental system of claim 1, wherein the third inlet pipeline is provided with an inlet master valve; the third inlet pipeline is connected to a drain pipe; and the drain pipe is provided with a drain valve.

5. The experimental system of claim 1, wherein the third outlet pipeline is provided with an outlet pressure regulating valve.

6. The experimental system of claim 1, wherein the third outlet pipeline is connected to a sampling pipe; and the sampling pipe is provided with a sampling valve.

7. The experimental system of claim 1, wherein the circulating pump is connected to a pump inverter; and the pump inverter is connected to the control and data acquisition system.

8. The experimental system of claim 1, wherein the control and data acquisition system is connected to a communication module; and the communication module is configured for communicating and interconnecting with an upper computer.

9. A method for operating the experimental system of claim 1, wherein the method comprises a constant-gap circulation mode, a constant-gap series mode, a constant-power circulation mode and a constant-power series mode;
the constant-gap circulation mode is performed through steps of:
setting, by the operation parameter control and detection device, a gap value of the disc refiner unit; selecting the first storage tank or the second storage tank as a circulating storage tank; opening the first inlet control valve and the first outlet control valve of the first storage tank and closing the second inlet control valve and the second outlet control valve of the second storage tank, or opening the second inlet control valve and the second outlet control valve of the second storage tank and closing the first inlet control valve and the first outlet control valve of the first storage tank; turning on the flowmeter, the disc refiner unit, the circulating pump, the first temperature and pressure measuring point and the second first temperature and pressure measuring point; maintaining, by the operation parameter control and detection device, a gap of the disc refiner unit at a set gap value; and transmitting measured experimental data to the control and data acquisition system;
the constant-gap series mode is performed through steps of:
setting, by the operation parameter control and detection device, a gap value of the disc refiner unit; selecting the first storage tank as an initial pre-refining tank and the second storage tank as a post-refining tank; closing the first inlet control valve of the first storage tank and opening the first outlet control valve or closing the second inlet control valve of the second storage tank and opening the second outlet control valve; opening the second inlet control valve of the second storage tank and closing the second outlet control valve or opening the first inlet control valve of the first storage tank and closing the first outlet control valve; turning on the flowmeter, the disc refiner unit, the circulating pump, the first temperature and pressure measuring point and the second temperature and pressure measuring point; maintaining, by the operation parameter control and detection device, a gap of the disc refiner unit at a set gap value; transmitting measured experimental data to the control and data acquisition system; and after a single refining is completed, interchanging the initial pre-refining tank and the post-refining tank, and repeating the above steps;
the constant-power circulation mode is performed through steps of:
setting, by the operation parameter control and detection device, a power value of the disc refiner unit; selecting the first storage tank or the second storage tank as a circulating storage tank; opening the first inlet control valve and the first outlet control valve of the first storage tank and closing the second inlet control valve and the second outlet control valve of the second storage tank, or opening the second inlet control valve and the second outlet control valve of the second storage tank and closing the first inlet control valve and the first outlet control valve of the first storage tank; turning on the flowmeter, the disc refiner unit, the circulating pump, the first temperature and pressure measuring point and the second temperature and pressure measuring point; maintaining, by the operation parameter control and detection device, a power of the disc refiner unit at a set power value; and transmitting measured experimental data to the control and data acquisition system; and
the constant-power series mode is performed through steps of:
setting, by the operation parameter control and detection device, a power value of the disc refiner unit; selecting the first storage tank as an initial pre-refining tank and the second storage tank as a post-refining tank; closing the first inlet control valve of the first storage tank and opening the first outlet control valve or closing the second inlet control valve of the second storage tank and opening the second outlet control valve; opening the second inlet control valve of the second storage tank and closing the second outlet control valve or opening the first inlet control valve of the first storage tank and closing the first outlet control valve; turning on the flowmeter, the disc refiner unit, the circulating pump, the first temperature and pressure measuring point and the second temperature and pressure measuring point; maintaining, by the operation parameter control and detection device, a power of the disc refiner unit at a set power value; transmitting measured experimental data to the control and data acquisition system; and after a single refining is completed, interchanging the initial pre-refining tank and the post-refining tank, and repeating the above steps.

10. The method of claim 9, wherein in each mode, when a refining test is carried out, a refined pulp is sampled to test quality thereof; and after the refining test is completed, the entire experimental system is drained and cleaned.
